(19) United States
(12) Patent Application Publication
(10) Pub. No.: US 2024/0389420 A1
(43) Pub. Date: Nov. 21, 2024

(54) DISPLAY SUBSTRATE, PREPARATION METHOD THEREFOR, AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Benlian WANG, Beijing (CN); Jianghua LIU, Beijing (CN); Ming HU, Beijing (CN); Haijun QIU, Beijing (CN)

(21) Appl. No.: 18/694,438

(22) PCT Filed: Aug. 2, 2023
(86) PCT No.: PCT/CN2023/110778

§ 371 Date: Mar. 22, 2024

(30) Foreign Application Priority Data
Aug. 9, 2022 (CN) 202210950011.0

(51) Int. Cl. H10K 59/35; H10K 59/12; H10K 59/131

(52) U.S. Cl. CPC H10K 59/352; H10K 59/1201; H10K 59/131; H10K 59/353

(57) ABSTRACT

A display substrate, comprising: a base, multiple first region light-emitting elements, multiple second region light-emitting elements, multiple first pixel circuits, and multiple second pixel circuits. The base comprises a first display area and, located on at least one side of the first display area, a second display area. The multiple first region light-emitting elements are located in the first display area and comprise multiple first light-emitting elements emitting first-color light. The multiple second region light-emitting elements, the multiple first pixel circuits, and the multiple second pixel circuits are located in the second display area. At least one first pixel circuit is electrically connected to n first light-emitting elements, and is configured to drive the n first light-emitting elements to emit light. And at least one first pixel circuit is electrically connected to m first light-emitting elements, and is configured to drive the m first light-emitting elements to emit light.

### CROSS-REFERENCE TO RELATED APPLICATIONS

The present application is a U.S. National Phase Entry of International Application PCT/CN2023/110778 having an international filing date of Aug. 2, 2023, which claims priority to Chinese Patent Application No. 202210950011.0 filed to the CNIPA on Aug. 9, 2022 and entitled “Display Substrate, Preparation Method Therefor, and Display Apparatus”, the contents of which are hereby incorporated by reference in their entireties.

### TECHNICAL FIELD

The present disclosure relates to, but is not limited to, the field of display technologies, and particularly to a display substrate, and a manufacturing method therefor, and a display device.

### BACKGROUND

With continuous development of display technologies, a camera is usually installed on a display device to meet shooting needs. In order to maximize a screen-to-body ratio, technologies such as notch screen, waterdrop screen, and under-screen punch hole have appeared successively. These technologies reduce an area occupied by a camera in a surrounding region by punching a hole locally in a display region and placing the camera under a punch-hole region, thus increasing the screen-to-body ratio. However, the above technologies requires cutting out part of the display region, which will cause some regions in a display picture to be unable to be displayed, and make it impossible to further improve the screen-to-body ratio.

### SUMMARY

The following is a summary of subject matter described herein in detail. This summary is not intended to limit the protection scope of the claims.

Embodiments of the present disclosure provide a display substrate, a method for manufacturing the display substrate, and a display device.

In one aspect, an embodiment of the present disclosure provides a display substrate including a base substrate, a plurality of first region light emitting elements, a plurality of second region light emitting elements, a plurality of first pixel circuits, and a plurality of second pixel circuits. The base substrate includes a first display region and a second display region located on at least one side of the first display region. A plurality of first region light emitting elements are located in the first display region and include a plurality of first light emitting elements emitting first color light. A plurality of second region light emitting elements, a plurality of first pixel circuits and a plurality of second pixel circuits are located in the second display region. At least one second pixel circuit is electrically connected to at least one second region light emitting element and is configured to drive the at least one second region light emitting element to emit light. At least one first pixel circuit is electrically connected to n first light emitting elements and is configured to drive the n first light emitting elements to emit light. At least one first pixel circuit is electrically connected to m first light emitting elements and is configured to drive the m first light emitting elements to emit light. Herein, m and n are integers greater than or equal to 2.

In some exemplary implementations, the m first light emitting elements are first light emitting units and the n first light emitting elements are second light emitting units, and the first light emitting units and the second light emitting units are arranged at intervals along the first direction.

In some exemplary implementations, m is an integer multiple of n.

In some exemplary implementations, m is not equal to n.

In some exemplary implementations, the display substrate further includes a plurality of first connection lines located in the first display region; the n first light emitting elements are electrically connected through one first connection line, and the m first light emitting elements are electrically connected through one first connection line. Each first connection line is in direct contact with anodes of the first light emitting elements to which the first connection line is electrically connected.

In some exemplary implementations, the display substrate further includes a plurality of second connection lines, and the n or the m first light emitting elements which are electrically connected through the first connection line are electrically connected to a first pixel circuit of the second display region through a second connection line.

In some exemplary implementations, the second connection lines are located on a side of the first connection lines close to the base substrate; a second connection line is electrically connected to the first connection line or an anode of at least one of the n first light emitting elements or the m first light emitting elements electrically connected to the first connection lines.

In some exemplary implementations, the first connection lines are located on a side of the anodes of the first light emitting elements close to the base substrate; and an organic insulation layer is provided between the second connection lines and the first connection lines, and the second connection lines are electrically connected to the first connection lines or the anodes of the first light emitting elements through via holes formed on the organic insulation layer.

In some exemplary implementations, materials of the first connection lines and second connection lines include transparent conductive materials.

In some exemplary implementations, m is 2 and n is 4. The m first light emitting elements are arranged sequentially along a second direction, and the n first light emitting elements are arranged in a 2×2 array, wherein the second direction intersects with the first direction.

In some exemplary implementations, the plurality of first region light emitting elements further include a plurality of second light emitting elements emitting second color light, and a plurality of third light emitting elements emitting third color light. At least one first pixel circuit is electrically connected to two second light emitting elements through a third connection line and a fourth connection line, and at least one first pixel circuit is electrically connected to two third light emitting elements through a fifth connection line and a sixth connection line; and the third connection line and the fifth connection line are located in the first display region, and the fourth connection line and the sixth connection line extend from the second display region to the first display region and are electrically connected to the at least one first pixel circuit.

In some exemplary implementations, the third connection line and the fifth connection line are arranged in a same layer as the first connection line, and the fourth connection line and the sixth connection line are arranged in a same layer as the second connection line.

In some exemplary implementations, the first color light is green light, the second color light is red light, and the third color light is blue light.

In some exemplary implementations, an orthographic projection of the fifth connection line on the base substrate is V-shaped. Herein, n or m is 4, and an orthographic projection of the first connection line electrically connected to four first light emitting elements on the base substrate is U-shaped.

In some exemplary implementations, a plurality of rows of first region light emitting elements which are interconnected constitute a set of first region light emitting elements, one row of first region light emitting elements comprise a plurality of first region light emitting elements arranged along the first direction, and the fourth connection line to which the second light emitting elements in the set of first region light emitting elements are electrically connected and the sixth connection line to which the third light emitting elements in the set of first region light emitting elements are electrically connected are located on a same side of the set of first region light emitting elements in the second direction; the second connection line to which the first light emitting elements in the set of first region light emitting elements are electrically connected and the fourth connection line to which the second light emitting elements are electrically connected are located on opposite sides of the set of first region light emitting elements in the second direction; and the second direction intersects with the first direction.

In some exemplary implementations, m and n are 3; and the m first light emitting elements and the n first light emitting elements are arranged in a 2×3 array. Two first light emitting elements located in a same column and two first light emitting elements located in a same row in the m first light emitting elements are electrically connected through a first connection line; and two first light emitting elements located in a same column and two first light emitting elements which are not located in a same row or a same column in the n first light emitting elements are electrically connected through the first connection line.

In another aspect, an embodiment of the present disclosure provides a display device, which includes the aforementioned display substrate.

On the other hand, an embodiment of the present disclosure provides a method for manufacturing a display substrate, including: preparing a plurality of first pixel circuits and a plurality of second pixel circuits in the second display region of the base substrate, preparing a plurality of first region light emitting elements in the first display region of the base substrate, and preparing a plurality of second region light emitting elements in the second display region. Herein, the second display region is located on at least one side of the first display region; the plurality of first region light emitting elements include a plurality of first light emitting elements emitting the first color light; at least one second pixel circuit is electrically connected to at least one second region light emitting element and is configured to drive the at least one second region light emitting element to emit light; at least one first pixel circuit is electrically connected to the n first light emitting elements and is configured to drive the n first light emitting elements to emit light; at least one first pixel circuit is electrically connected to the m first light emitting elements and is configured to drive the m first light emitting elements to emit light; wherein m and n are integers greater than or equal to 2, and m is not equal to n.

In some exemplary implementations, after the plurality of first pixel circuits and the plurality of second pixel circuits are prepared in the second display region of the base substrate, a plurality of first region light emitting elements are prepared in the first display region of the base substrate, and before the plurality of second region light emitting elements are prepared in the second display region, the manufacturing method further includes forming a second transparent conductive layer which includes a plurality of second connection lines, and forming a first transparent conductive layer in the first display region. The first transparent conductive layer includes a plurality of first connection lines; the n first light emitting elements are electrically connected through one first connection line, the m first light emitting elements are electrically connected through one first connection line, and the n first light emitting elements or the m first light emitting elements which are electrically connected through the one first connection line are electrically connected to a first pixel circuit of the second display region through a second connection line.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a schematic diagram of a display substrate according to at least one embodiment of the present disclosure.

FIG. 2 is a partial schematic view of a display substrate according to at least one embodiment of the present disclosure;

FIG. 3 is a schematic partial plan view of a display substrate according to at least one embodiment of the present disclosure;

FIG. 4 is a schematic diagram of traces connection of a display substrate according to at least one embodiment of the present disclosure.

FIG. 5 is a schematic diagram of traces connection of a display substrate according to at least one embodiment of the present disclosure.

FIG. 6 is a schematic diagram of traces connection of a display substrate according to at least one embodiment of the present disclosure.

FIG. 7 is a schematic partial sectional view of a display substrate according to at least one embodiment of the present disclosure.

FIG. 8 is another schematic partial plan view of a display substrate according to at least one embodiment of the present disclosure.

FIG. 9 is another schematic partial plan view of a display substrate according to at least one embodiment of the present disclosure.

FIG. 10 is another schematic partial plan view of a display substrate according to at least one embodiment of the present disclosure.

FIG. 11 is a schematic diagram of a display device according to at least one embodiment of the present disclosure.

### DETAILED DESCRIPTION

The embodiments of the present disclosure will be described below with reference to the drawings in detail. Implementations may be practiced in multiple different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limitations on numbers but only to avoid confusion between composition elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or an internal communication inside two elements. Those of ordinary skills in the art may understand meanings of the aforementioned terms in the present disclosure according to situations.

In the specification, “electrical connection” includes connection of composition elements through an element with a certain electrical action. The “element with a certain electrical action” is not particularly limited as long as electrical signals between the connected constituent elements may be transmitted. Examples of the “element with a certain electrical action” not only include an electrode and a wiring, but also include a switching element such as a transistor, a resistor, an inductor, a capacitor, another element with multiple functions, etc.

In the specification, a transistor refers to an element which at least includes three terminals, i.e., a gate, a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, a first electrode may be a drain and a second electrode may be a source, or, a first electrode may be a source and a second electrode may be a drain. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, and deformation, etc.

A “light transmittance” in the present disclosure refers to an ability of light to pass through a medium, and is a percentage of luminous flux passing through a transparent or translucent body to its incident luminous flux.

In the present disclosure, “about” and “substantially” refer to that a boundary is not defined strictly and a case within a range of process and measurement errors is allowed. In the present disclosure, “substantially the same” refers to a case where numerical values differ by less than 10%.

An embodiment of the present disclosure provides a display substrate including a base substrate, a plurality of first region light emitting elements, a plurality of second region light emitting elements, a plurality of first pixel circuits, and a plurality of second pixel circuits. The base substrate includes a first display region and a second display region located on at least one side of the first display region. The plurality of first region light emitting elements are located in the first display region and include a plurality of first light emitting elements emitting first color light. The plurality of second region light emitting elements, the plurality of first pixel circuits and the plurality of second pixel circuits are located in the second display region. At least one second pixel circuit is electrically connected to at least one second region light emitting element and is configured to drive the at least one second region light emitting element to emit light. At least one first pixel circuit is electrically connected to n first light emitting elements and is configured to drive the n first light emitting elements to emit light. At least one first pixel circuit is electrically connected to m first light emitting elements and is configured to drive the m first light emitting elements to emit light. Herein, m and n are integers greater than or equal to 2.

In some examples, m may be an integer multiple of n. For example, m may be equal to n, or m may be twice of n. For example, m may be 2, and n may be 4. However, the embodiment is not limited thereto.

In some examples, m may not be equal to n. For example, m may be 2, and n may be 4; or m may be 2, and n may be 3; or m may be 3, and n may be 4.

In some examples, values of m and n may be less than or equal to 8 to ensure a display effect when one first pixel circuit drives n or m first light emitting elements.

According to the display substrate provided by this embodiment, for the first light emitting elements emitting the first color light, n first light emitting elements share one first pixel circuit, and m first light emitting elements share one first pixel circuit (for example, there may be two corresponding relationships between the first pixel circuit and the first light emitting elements, i.e., one first pixel circuit driving m first light emitting elements and one first pixel circuit driving n first light emitting elements), so that a quantity of connection lines between the first pixel circuit and the first light emitting elements may be reduced. The display substrate according to this embodiment may ensure a quality of the display picture and reduce a cost of the display substrate.

In some exemplary implementations, the m first light emitting elements are first light emitting units and the n first light emitting elements are second light emitting units, and the first light emitting units and the second light emitting units may be arranged at intervals along the first direction. In this example, the first light emitting units and the second light emitting units are arranged at intervals, which is beneficial to ensuring the display effect of the display substrate.

In some exemplary implementations, the display substrate may further include a plurality of first connection lines located in the first display region. n first light emitting elements may be electrically connected through one first connection line, and m first light emitting elements may be electrically connected through one first connection line. In some examples, one first connection line may be in direct contact with anodes of n first light emitting elements or m first light emitting elements electrically connected thereto. In this example, the first connection line is electrically connected by directly lapping with the anodes of the first light emitting elements, without a switching by punching a hole on an insulation layer, which is beneficial to simplifying manufacturing processes and reducing a manufacturing cost of the display substrate.

In some exemplary implementations, the display substrate may further include a plurality of second connection lines. n or m first light emitting elements electrically connected through the first connection line may be electrically connected to the first pixel circuit of the second display region through the second connection line. In some examples, the second connection line may extend from the first display region to the second display region and be electrically connected to the first pixel circuit in the second display region, and the second connection line may be electrically connected to the first connection line or an anode of at least one of the n first light emitting elements or the m first light emitting elements electrically connected to the first connection line in the first display region.

In some exemplary implementations, the first connection line may be located on a side of the anodes of the first light emitting elements close to the base substrate, and the second connection line may be located on a side of the first connection line close to the base substrate. An organic insulation layer may be provided between the second connection line and the first connection line, and the second connection line may be electrically connected to the first connection line or the anode of the first light emitting element through a via hole formed on the organic insulation layer. In this example, the electrical connection between the first light emitting elements and the first pixel circuit is achieved by a combination of the first connection line and the second connection line, which may simplify the manufacturing processes and reduce the manufacturing cost of the display substrate.

In some exemplary implementations, materials of the first connection lines and second connection lines may include transparent conductive materials. In this example, a light transmittance of the first display region may be ensured by using the first connection lines and the second connection lines which are made of transparent conductive materials.

Solutions of the embodiments will be described below through some examples.

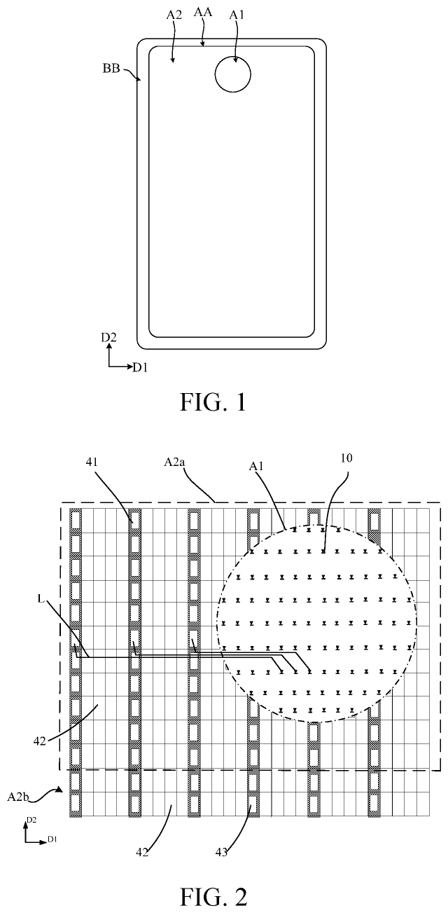

FIG. 1 is a schematic diagram of a display substrate according to at least one embodiment of the present disclosure. In some examples, as shown in FIG. 1, the display substrate may include a display area AA and a peripheral area BB surrounding a periphery of the display area AA. The display area AA of the display substrate may include a first display region A1 and a second display region A2. The second display region A2 may at least partially surround the first display region A1. In the example, the second display region A2 may surround a periphery of the first display region A1.

In some examples, as shown in FIG. 1, the first display region A1 may be a light-transmitting display region, and may also be referred to as a Full Display with Camera (FDC) region, and the second display region A2 may be a normal display region. For example, an orthographic projection of a photosensitive sensor (such as a camera and other hardware) on the display substrate may be within the first display region A1 of the display substrate. In some examples, as shown in FIG. 1, the first display region A1 may be circular and a size of the orthographic projection of the photosensitive sensor on the display substrate may be less than or equal to a size of the first display region A1. However, the embodiment is not limited thereto. In some other examples, the first display region A1 may be rectangular, and a size of the orthographic projection of the photosensitive sensor on the display substrate may be less than or equal to a size of an inscribed circle of the first display region A1.

In some examples, as shown in FIG. 1, the first display region A1 may be located at a middle position of the top of the display area AA. The second display region A2 may surround the periphery of the first display region A1. However, the embodiment is not limited thereto. For example, the first display region A1 may be located at another position such as an upper left corner or an upper right corner of the display area AA. For example, the second display region A2 may surround at least one side of the first display region A1.

In some examples, as shown in FIG. 1, the display area AA may be in a shape of a rectangle, e.g., a rounded rectangle. The first display region A1 may be circular or elliptical. However, the embodiment is not limited thereto. For example, the first display region A1 may be rectangular, semicircular, pentagonal, or have another shape.

In some examples, the display area AA may be provided with a plurality of sub-pixels. At least one sub-pixel may include a pixel circuit and a light emitting element. The pixel circuit may be configured to drive a light emitting element connected thereto. For example, the pixel circuit is configured to provide a drive current to drive the light emitting element to emit light. The pixel circuit may include a plurality of transistors and at least one capacitor. For example, the pixel circuit may be of a 3T1C, 4T1C, 5T1C, 5T2C, 6T1C, 7T1C, or 8T1C structure. Among them, in the above circuit structure, T refers to a thin film transistor, C refers to a capacitor, a number before T represents a quantity of thin film transistors in the circuit, and a number before C represents a quantity of capacitors in the circuit.

In some examples, the plurality of transistors in the pixel circuit may be P-type transistors or may be N-type transistors. Use of a same type of transistors in the pixel circuit may simplify a process flow, reduce a process difficulty of the display substrate, and improve a yield of products. In some other examples, the plurality of transistors in the pixel circuit may include a P-type transistor and an N-type transistor.

In some examples, low temperature poly silicon thin film transistors, or oxide thin film transistors, or a low temperature poly silicon thin film transistor and an oxide thin film transistor may be used as the plurality of transistors in the pixel circuit. Low Temperature Poly Silicon (LTPS) is used for an active layer of a low temperature poly silicon thin film transistor and an oxide semiconductor (Oxide) is used for an active layer of an oxide thin film transistor. The low temperature poly silicon thin film transistor has advantages such as a high migration rate and fast charging, and the oxide thin film transistor has advantages such as a low leakage current. The low temperature poly silicon thin film transistor and the oxide thin film transistor are integrated on one display substrate, that is, an LTPS+Oxide (LTPO for short) display substrate, advantages of both the low temperature poly silicon thin film transistor and the oxide thin film transistor may be utilized, so that low-frequency drive may be achieved, power consumption may be reduced, and display quality may be improved.

In some examples, the light emitting element may be any one of a Light Emitting Diode (LED), an Organic Light emitting Diode (OLED), a Quantum dot Light emitting Diode (QLED), a Micro LED (including a mini-LED or a micro-LED) and the like. For example, the light emitting element may be an OLED, and the light emitting element may emit red light, green light, blue light, or white light, etc. under drive of a pixel circuit corresponding to the light emitting element. A color of light emitted by the light emitting element may be determined as required. In some examples, the light emitting element may include an anode, a cathode, and an organic emitting layer located between the anode and the cathode. The anode of the light emitting element may be electrically connected to a corresponding pixel circuit. However, the embodiment is not limited thereto.

In some examples, one pixel unit of the display area AA may include three sub-pixels, and the three sub-pixels may be a red sub-pixel, a green sub-pixel, and a blue sub-pixel, respectively. However, the embodiment is not limited thereto. In some examples, one pixel unit may include four sub-pixels, wherein the four sub-pixels may be a red sub-pixel, a green sub-pixel, a blue sub-pixel, and a white sub-pixel respectively.

In some examples, a shape of the light emitting element may be a rectangle, a rhombus, a pentagon, or a hexagon. When one pixel unit includes three sub-pixels, light emitting elements of the three sub-pixels may be arranged side by side horizontally, side by side vertically, or in a delta-shaped arrangement. When one pixel unit includes four sub-pixels, light emitting elements of the four sub-pixels may be arranged side by side horizontally, side by side vertically, or in a square arrangement. However, the embodiment is not limited thereto.

FIG. 2 is a partial schematic view of a display substrate according to at least one embodiment of the present disclosure. In some examples, as shown in FIG. 2, the second display region A2 of the display substrate may include a transition region A2a and a non-transition region A2b. The transition region A2a may be located on at least one side outside the first display region A1 (for example, one side; for another example, left and right sides; for another example, all around, i.e., including upper and lower sides and left and right sides).

In some examples, as shown in FIG. 2, the first display region A1 may include a plurality of first region light emitting elements 10 arranged in an array. The transition region A2a of the second display region A2 may include a plurality of first pixel circuits 41 and a plurality of second pixel circuits 42 arranged in an array and may further include a plurality of second region light emitting elements (not shown). At least one first pixel circuit 41 in the transition region A2a may be electrically connected to at least two first region light emitting elements 10 through a connection line L, and is configured to drive the at least two first region light emitting elements 10 to emit light. For example, one first pixel circuit 41 may be configured to drive two or three or four first region light emitting elements 10 emitting the same color light to emit light. An orthographic projection of the first region light emitting elements 10 on the base substrate may be not overlapped with an orthographic projection of the first pixel circuit 41 electrically connected thereto on the base substrate. At least one second pixel circuit 42 in the transition region A2a may be electrically connected to at least one second region light emitting element and is configured to drive the at least one second region light emitting element to emit light. For example, one second pixel circuit 42 may be configured to drive one second region light emitting element to emit light. An orthographic projection of the second pixel circuit 42 may be at least partially overlapped with an orthographic projection of the second region light emitting element electrically connected thereto on the base substrate. In the example, by arranging a first pixel circuit 41 for driving the first region light emitting elements in the transition region A2a, sheltering of light by a pixel circuit may be reduced, thereby increasing a light transmittance of the first display region A1.

In some examples, as shown in FIG. 2, the non-transition region A2b may include a plurality of second pixel circuits 42 and a plurality of invalid pixel circuits 43 arranged in an array, and may further include a plurality of second region light emitting elements. The transition region A2a may further include a plurality of invalid pixel circuits 43. It may be beneficial to improving uniformity of components of a plurality of film layers in an etching process by arranging an invalid pixel circuit 43. For example, a structure of a invalid pixel circuit 43 may be substantially the same as structures of a first pixel circuit 41 and a second pixel circuit 42 of a row or column in which the invalid pixel circuit is located, except that it is not electrically connected to any light emitting element.

In some examples, since the second display region A2 is not only provided with the second pixel circuits 42 electrically connected to the second region light emitting elements, but also provided with the first pixel circuits 41 electrically connected to the first region light emitting elements 10, the quantity of pixel circuits of the second display region A2 may be greater than the quantity of second region light emitting elements. In some examples, as shown in FIG. 2, a region where newly added pixel circuits (including a first pixel circuit and an invalid pixel circuit) are arranged may be obtained by reducing a size of a second pixel circuit in a first direction D1. For example, a dimension of a pixel circuit in the first direction D1 may be smaller than a dimension of a second region light emitting element in the first direction D1. In this example, as shown in FIG. 2, original a columns of pixel circuits may be compressed along the first direction D1, so that arrangement space of one column of pixel circuits may be newly added, and space occupied by a columns of pixel circuits before compression and space occupied by a+1 columns of pixel circuits after compression may be the same. Herein, a may be an integer greater than 1. In some examples, a may be equal to 4. However, the embodiment is not limited thereto. For example, a may be equal to 2 or 3.

In some other examples, original b rows of pixel circuits may be compressed along a second direction D2, so that arrangement space of one row of pixel circuits is newly added, and space occupied by b rows of pixel circuits before compression and space occupied by b+1 rows of pixel circuits after compression are the same. Herein, “b” may be an integer greater than 1. Or, a region in which a newly added pixel circuit is disposed may be obtained by reducing dimensions of a second pixel circuit in the first direction D1 and the second direction D2.

In an embodiment of the present disclosure, a row of light emitting elements may refer to that pixel circuits connected to the row of light emitting elements are all connected to a same gate line (for example, a scan line). One row of pixel circuits may refer to a plurality of pixel circuits sequentially arranged along the first direction, and one row of pixel circuits may be all connected to the same gate line. However, the embodiment is not limited thereto.

In some implementations, the connection line L may be made of a transparent conductive material to improve the light transmittance of the display substrate and ensure a photographing effect. Taking that a length of the first display region along the second direction is about 3 mm and a length of each first region light emitting elements along the second direction is about 60 microns as an example, about 80×40 first region light emitting elements may be arranged in the first display region, all of which need to be electrically connected to the first pixel circuits of the second display region through connection lines. Each row of first region light emitting elements needs to be electrically connected to the first pixel circuits of the second display region on the left side through 40 connection lines, and also needs to be electrically connected to the first pixel circuits of the second display region on the right side through 40 connection lines. A width (i.e., a length along the second direction) of each connection lines made of the transparent conductive material is about 4 microns. For a single transparent conductive layer, only 60/4=15 connection lines may be arranged for one row of first region light emitting elements. In order to meet the quantity of connection lines connected to each row of first region light emitting elements, 40/15=2.67 transparent conductive layers are needed, and thus three transparent conductive layers are needed. It can be seen that due to the size and process limitation of connection lines made of transparent conductive materials, three transparent conductive layers are needed to arrange connection lines, which greatly affects the productivity and has high cost.

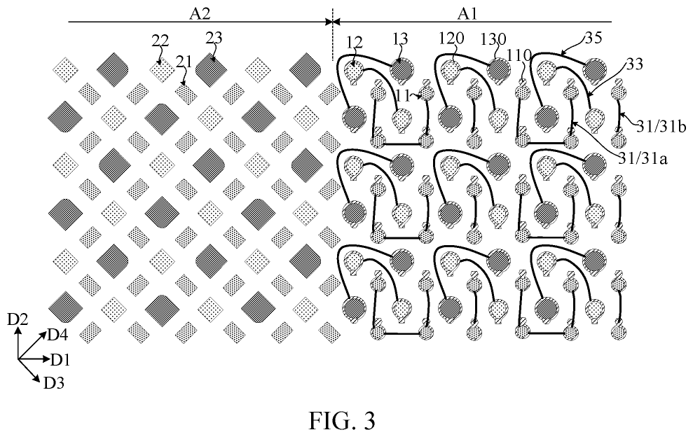

FIG. 3 is a schematic partial plan view of a display substrate according to at least one embodiment of the present disclosure. In some examples, as shown in FIG. 3, the first display region A1 of the display substrate may include a plurality of first region light emitting elements, which may include: a plurality of first light emitting elements 11 emitting first color light, a plurality of second light emitting elements 12 emitting second color light, and a plurality of third light emitting elements 13 emitting third color light. In some examples, the first color light may be green light, the second color light may be red light, and the third color light may be blue light. However, the embodiment is not limited thereto.

In some examples, as shown in FIG. 3, each first light emitting element 11 may include an anode 110, an organic light emitting layer and a cathode. Each second light emitting element 12 may include an anode 120, an organic light emitting layer and a cathode. Each third light emitting element 13 may include an anode 130, an organic light emitting layer and a cathode. The cathodes of the first light emitting elements 11, the second light emitting elements 12, and the third light emitting elements 13 may be of an integral structure.

In some examples, as shown in FIG. 3, one pixel unit of the first display region A1 may include four first region light emitting elements (e.g. including two first light emitting elements 11, one second light emitting element 12 and one third light emitting element 13). The two first light emitting elements 11, the one second light emitting element 12, and the one third light emitting element 13 may be arranged in a Diamond manner to form a RGBG pixel arrangement. For example, the second light emitting element 12 and the third light emitting element 13 may be arranged at intervals in a same row along the first direction D1 and arranged at intervals in a same column along the second direction D2, and the first light emitting elements 11 may be sequentially arranged in a same row along the first direction D1 and sequentially arranged in a same column along the second direction D2. The rows in which the second light emitting elements 12 and the third light emitting elements 13 are located and the rows in which the first light emitting elements 11 are located are arranged at intervals, and the columns in which the second light emitting elements 12 and the third light emitting elements 13 are located and the columns of the first light emitting elements 11 are arranged at intervals. The first direction D1 may intersect with the second direction D2. For example, the first direction D1 may be perpendicular to the second direction D2.

In some examples, as shown in FIG. 3, the second display region A2 of the display substrate may include a plurality of second region light emitting elements, which may include a plurality of fourth light emitting elements 21 emitting the first color light, a plurality of fifth light emitting elements 22 emitting the second color light, and a plurality of sixth light emitting elements 23 emitting the third color light. The arrangement of the fourth light emitting elements 21, the fifth light emitting elements 22, and the sixth light emitting elements 23 may be the same as the arrangement of the first light emitting elements 11, the second light emitting elements 12, and the third light emitting elements 13 in the first display region A1, which will not be repeated here.

In some examples, as shown in FIG. 3, an area of a light emitting region of a first region light emitting element may be smaller than an area of a light emitting region of a second region light emitting element emitting the same color light. Herein, an area of a light emitting region of a first light emitting element 11 may be smaller than an area of a light emitting region of a fourth light emitting element 21. An area of a light emitting region of a second light emitting element 12 may be smaller than an area of a light emitting region of a fifth light emitting elements 22. An area of a light emitting region of a third light emitting element 13 may be smaller than an area of a light emitting region of a sixth light emitting elements 23. For example, the second region light emitting element may be quadrilateral or pentagonal, and the first region light emitting element may be circular or elliptical. In this example, the light transmittance of the first display region may be improved and a diffraction condition may be improved by reducing the areas of the light emitting regions of the first region light emitting elements.

In this example, a light emitting region of a light emitting element refers to an overlapping region between the anode, the organic light emitting layer and the cathode of the light emitting element, that is, a connection region between the anode exposed by a pixel opening of a pixel definition layer, and the organic light emitting layer as well as the cathode.

In some examples, as shown in FIG. 3, the first display region A1 may further be provided with a plurality of first connection lines 31, a plurality of third connection lines 33 and a plurality of fifth connection lines 35. One first connection line 31 may be electrically connected to anodes 110 of two or four first light emitting elements 11. In this example, m may be 4, and n may be 2. The plurality of first connection lines 31 may include a plurality of first type first connection lines 31a and a plurality of second type first connection lines 31b. The first type first connection line 31a may be configured to electrically connect four adjacent first light emitting elements 11, and each second type first connection line 31b may be configured to electrically connect two adjacent first light emitting elements 11. The first type first connection line 31a may electrically connect four first light emitting elements 11 arranged in a 2×2 array, and an orthographic projection of the first type first connection line 31a on the base substrate may be U-shaped. The U-shape formed by the first type first connection line 31a may partially surround one second light emitting element 12 or one third light emitting element 13. The second type first connection line 31b may electrically connect two adjacent first light emitting elements 11 arranged along the second direction D2, and an orthographic projection of the second type first connection line 31b on the base substrate may be I-shaped. The four first light emitting elements 11 electrically connected by the first type first connection line 31a may be first light emitting units, and two first light emitting elements 11 electrically connected by the second type first connection line 31b may be second light emitting units. The first light emitting units and the second light emitting units may be arranged at intervals along the first direction D1. In the first direction D1, the first type first connection lines 31a and the second type first connection lines 31b may be arranged at intervals. In other words, the two rows of first light emitting elements 11 arranged along the first direction D1 may be electrically connected in sequence according to a rule that four first light emitting elements are electrically connected and two first light emitting elements are electrically connected. For the two rows of first light emitting elements 11, two first light emitting elements 11 arranged in the first direction D1 and electrically connected by the first type first connection line 31a, and one first light emitting element 11 electrically connected by the second type first connection line 31b may be located in a same row and adjacent in the first direction D1. Two first light emitting elements 11 of the other row arranged along the first direction D1 and electrically connected by the first type first connection line 31a, and the other first light emitting element 11 electrically connected by the second type first connection line 31b may be located in a same row and adjacent in the first direction D1.

In some examples, as shown in FIG. 3, one third connection line 33 may be configured to be electrically connected to the anodes 120 of the second light emitting elements 12. The two second light emitting elements 12 electrically connected by the third connection line 33 may be located in different rows, and the two second light emitting elements 12 are spaced apart by one first light emitting element 11 in a third direction D3. The third direction D3 intersects with both the first direction D1 and the second direction D2. One fifth connection line 35 may be configured to be electrically connected to anodes 130 of two third light emitting elements 13. The two third light emitting elements 13 electrically connected by the fifth connection line 35 are located in different rows, and the two third light emitting elements 13 are spaced apart by one first light emitting element 11 in a fourth direction D4. An orthographic projection of the fifth connection line 35 on the base substrate may be V-shaped. One second light emitting element 12 may be located in the V-shape formed by the fifth connection line 35. The fourth direction D4 intersects with both the first direction D1 and the second direction D2. For example, the fourth direction D4 may be perpendicular to the third direction D3. The two second light emitting elements 12 electrically connected by the third connection line 33 and the two third light emitting elements 13 electrically connected by the fifth connection line 35 may be arranged in a 2×2 array, and the two second light emitting elements 12 are arranged diagonally and the two third light emitting elements 13 are arranged diagonally.

In some examples, as shown in FIG. 3, the first connection line 31, the third connection line 33, and the fifth connection line 35 may be disposed in a same layer, and orthographic projections of the first connection line 31, the third connection line 33, and the fifth connection line 35 on the base substrate may be not overlapped.

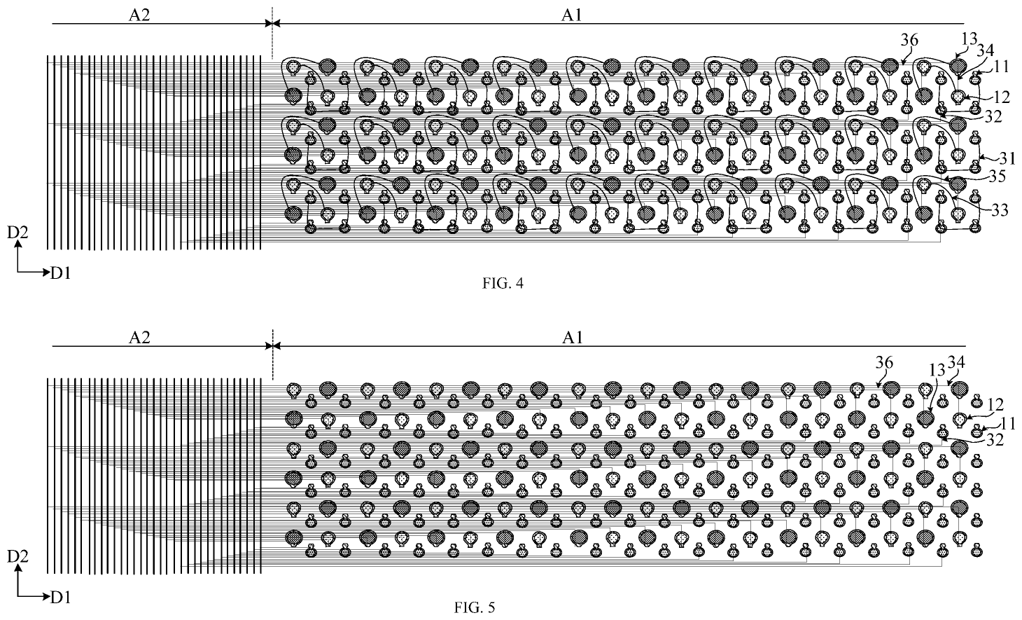

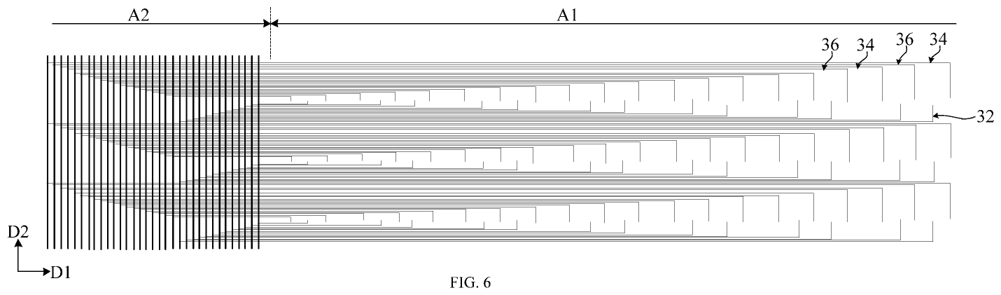

FIG. 4 to FIG. 6 are schematic diagrams of traces connection of a display substrate according to at least one embodiment of the present disclosure. A plurality of first region light emitting elements, a first connection line 31, a third connection line 33 and a fifth connection line 35 which are located in the first display region A1, and a second connection line 32, a fourth connection line 34 and a sixth connection line 36 which extend from the first display region A1 to the second display region A2 are illustrated in FIG. 4. A plurality of first region light emitting elements which are located in the first display region A1, and a second connection line 32, a fourth connection line 34 and a sixth connection line 36 which extend from the first display region A1 to the second display region A2 are illustrated in FIG. 5. A second connection line 32, a fourth connection line 34 and a sixth connection line 36 which extend from the first display region A1 to the second display region A2 are illustrated in FIG. 6. Each straight line in the second display region A2 in FIG. 4 to FIG. 6 indicates a column in which a first pixel circuit is located.

In some examples, as shown in FIG. 4 to FIG. 6, the display substrate may further include: a plurality of second connection lines 32, a plurality of fourth connection lines 34, and a plurality of sixth connection lines 36 extending from the first display region A1 to the second display region A2. Each second connection line 32 may be configured to electrically connect a first pixel circuit of the second display region A2 and four or two first light emitting elements 11 of the first display region A1. Each fourth connection line 34 may be configured to electrically connect a first pixel circuit of the second display region A2 and two second light emitting elements 12 of the first display region A1. Each sixth connection line 36 may be configured to electrically connect a first pixel circuit of the second display region A2 and two third light emitting elements 13 of the first display region A1.

In some examples, as shown in FIG. 4 to FIG. 6, the second connection line 32 may be electrically connected to an anode of one of the two or four first light emitting elements 11 to which the first connection line 31 is electrically connected. The fourth connection line 34 may be electrically connected to an anode of one of the two second light emitting elements 12 to which the third connection line 33 is electrically connected. The sixth connection line 36 may be electrically connected to an anode of one of the two third light emitting elements 13 to which the fifth connection line 35 is electrically connected. However, the embodiment is not limited thereto. In some other examples, the second connection line 32 may be electrically connected to the first connection line 31, thereby achieving an electrical connection with two or four first light emitting elements 11, the fourth connection line 34 may be electrically connected to the third connection line 33, thereby achieving an electrical connection with the two second light emitting elements 12, and the sixth connection line 36 may be electrically connected to the fifth connection line 35, thereby achieving an electrical connection with the two third light emitting elements 13.

In some examples, as shown in FIG. 4 to FIG. 6, the second connection line 32, the fourth connection line 34 and the sixth connection line 36 may disposed in a same layer. The second connection line 32, the fourth connection line 34, and the sixth connection line 36 may not be overlapped.

In some examples, as shown in FIG. 4 to FIG. 6, two adjacent rows of first light emitting elements having a connection relationship therebetween and two adjacent rows of second light emitting elements and third light emitting elements having a connection relationship therebetween are taken as a set of first region light emitting elements. The fourth connection line 34 and the sixth connection line 36 may be located on a same side of the set of first region light emitting elements in the second direction D2, and for example, in the second direction D2, the fourth connection line 34 and the sixth connection line 36 may be arranged at an interval. The second connection line 32 and the fourth connection line 34 may be located on different sides of the set of first region light emitting elements in the second direction D2, and the second connection lines 32 and the sixth connection line 36 may be located on different sides of the set of first region light emitting elements in the second direction D2. In this example, the second connection line 32, the fourth connection line 34 and the sixth connection line 36 are arranged on different sides of a set of first region light emitting elements in the second direction D2, which is beneficial for arrangement of the traces and may save arrangement space of the traces.

In some examples, as shown in FIG. 4 and FIG. 5, a first region light emitting element close to a center of the first display region A1 may be electrically connected to a first pixel circuit away from the first display region A1, and a first region light emitting element close to an edge of the first display region A1 may be electrically connected to a first pixel circuit close to the first display region A1. The first pixel circuit to which the first light emitting element 11 is electrically connected is closer to the first display region A1 than the first pixel circuit to which the second light emitting element 12 and the third light emitting element 13 are electrically connected. The connection mode of this example is beneficial for the second connection line, the fourth connection line and the sixth connection line to be arranged in the same conductive layer.

According to the display substrate provided by this example, four first light emitting elements may be driven through one first pixel circuit by using the first type first connection line and the second connection line, two first light emitting elements may be driven through one first pixel circuit by using the second type first connection line and the second connection line, two second light emitting elements may be driven through one first pixel circuit by using the third connection line and the fourth connection line, and two third light emitting elements may be driven through one first pixel circuit by using the fifth connection line and the sixth connection line. The connection mode adopted by the display substrate in this example may ensure the quality of display picture of the display substrate, and may also reduce the quantity of connection lines, thereby reducing the cost of the display substrate.

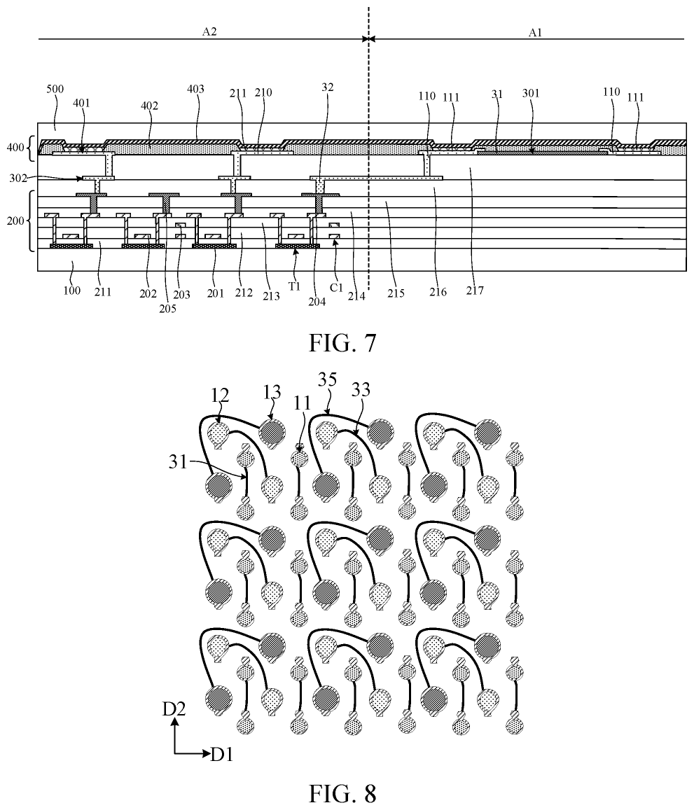

FIG. 7 is a schematic partial sectional view of a display substrate according to at least one embodiment of the present disclosure. In some examples, as shown in FIG. 7, in a direction perpendicular to the display substrate, the second display region A2 may include: a base substrate 100, and a circuit structure layer 200, a second transparent conductive layer 302, a first transparent conductive layer 301, a light emitting structure layer 400 and an encapsulation structure layer 500 which are sequentially arranged on the base substrate 100. The first display region A1 may include: the base substrate 100, and a composite insulation layer, a second transparent conductive layer 302, a light emitting structure layer 400, and an encapsulation structure layer 500 which are sequentially arranged on the base substrate 100. The circuit structure layer 200 of the second display region A2 may include: a semiconductor layer 201, a first insulation layer 211, a first gate metal layer 202, a second insulation layer 212, a second gate metal layer 203, a third insulation layer 213, a first source-drain metal layer 204, a fourth insulation layer 214, a fifth insulation layer 215, and a second source-drain metal layer 205 which are sequentially arranged on the base substrate 100. A sixth insulation layer 216 is provided between the circuit structure layer 200 and the second transparent conductive layer 302. A seventh insulation layer 217 may be provided between the second transparent conductive layer 302 and the first transparent conductive layer 301. The composite insulation layer of the first display region A1 may include: a first insulation layer 211, a second insulation layer 212, a third insulation layer 213, a fourth insulation layer 214, a fifth insulation layer 215, and a sixth insulation layer 216 which are stacked sequentially.

In some examples, the first insulation layer 211 to the fourth insulation layer 214 may all be inorganic insulation layers, and the fifth insulation layer 215 to the seventh insulation layer 217 may be organic insulation layers. The fifth insulation layer 215 to the seventh insulation layer 217 may also be referred to as planarization layers. However, the embodiment is not limited thereto. In some other examples, only the fifth insulation layer may be arranged between the first source-drain metal layer 204 and the second source-drain metal layer 205.

In some examples, as shown in FIG. 7, the light emitting structure layer 400 may include: an anode layer 401, a pixel definition layer 402, an organic emitting layer 302, and a cathode layer 403 which are sequentially arranged on the base substrate 100. The anode layer 401 may be electrically connected to pixel circuits of the circuit structure layer 200, the organic light emitting layer may be connected to the anode layer 401, and the cathode layer 403 may be connected to the organic light emitting layer. The organic emitting layer may emit light of a corresponding color under drive of the anode layer 401 and the cathode layer 403. The encapsulation structure layer 900 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer may be arranged between the first encapsulation layer and the third encapsulation layer to form a stacked structure of inorganic material/organic material/inorganic material, which may ensure that external moisture cannot enter the light emitting structure layer. In some possible implementations, the display substrate may further include another film layers, such as a touch structure layer, a color filter layer, or the like, which is not limited here in the present disclosure.

Exemplary description is made below for a structure and a manufacturing process of a display substrate. A “patterning process” mentioned in the embodiments of the present disclosure includes a treatment such as photoresist coating, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a material on a base substrate by using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B have a same layer structure” or “A and B are disposed in a same layer” mentioned in the embodiments of the present disclosure means that A and B are formed simultaneously through a same patterning process, or surfaces of A and B close to a base substrate have basically a same distance from the base substrate, or surfaces of A and B close to the base substrate are in direct contact with a same film layer. A “thickness” of a film layer is a dimension of the film layer in a direction perpendicular to the display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In some exemplary implementations, a manufacturing process of the display substrate may include following operations.
(1) A base substrate is provided. In some examples, the base substrate 100 may be a rigid base substrate, or may be a flexible base substrate. For example, the rigid base substrate may be made of, but not limited to, one or more of glass and quartz. The flexible base substrate may be made of, but not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In some examples, the flexible base substrate may include a first flexible material layer, a first inorganic material layer, a second flexible material layer and a second inorganic material layer which are stacked. The first flexible material layer and the second flexible material layer may be made of a material such as polyimide (PI), polyethylene terephthalate (PET), or a polymer soft film on which surface treatment is performed. Materials of the first inorganic material layer and the second inorganic material layer may be silicon nitride (SiNₓ) or silicon oxide (SiOₓ), etc., which are used to improve the base substrate's resistance ability against water and oxygen.
(2) A semiconductor layer is formed. In some examples, a semiconductor thin film is deposited on the base substrate 100, and the semiconductor thin film is patterned through a patterning process to form a semiconductor layer 201 in the second region A2. In some examples, a material of the semiconductor layer 201 may be amorphous Silicon (a-Si), polycrystalline Silicon (p-Si), hexathiophene or polythiophene, and another material.

In some examples, the semiconductor layer 201 of the second display region A2 may include: active layers of a plurality of transistors of a plurality of pixel circuits (e.g. an active layer of the first transistor T1). An active layer of a transistor may include a first region, a second region, and a channel region located between the first region and the second region. In some examples, the first region and the second region of the active layer may be interpreted as a source electrode or a drain electrode of a transistor. A part of the active layer between the transistors may be interpreted as a wiring doped with an impurity, and may be used for electrically connecting the transistors. The channel region may not be doped with an impurity, and has characteristics of a semiconductor. The first region and the second region located on two sides of the channel region may be doped with impurities and thus have electrical conductivity. The impurities may be changed according to a type of a transistor. However, the embodiment is not limited thereto.
(3) A first gate metal layer is formed. In some examples, a first insulation thin film and a first conductive thin film are sequentially deposited on the base substrate 100 where the aforementioned structure is formed, and the first conductive thin film is patterned through a patterning process to form a first insulation layer 211 covering the semiconductor layer 201, and the first gate metal layer 202 arranged on the first insulation layer 211 in the second display region A2. In some examples, the first gate metal layer 202 may include: gate electrodes of transistors of a plurality of pixel circuits and one plates of each of storage capacitors (e.g., including a gate electrode of a first transistor T1, a first plate of a first capacitor C1).
(4) A second gate metal layer is formed. In some examples, a second insulation thin film and a second conductive thin film are sequentially deposited on the base substrate 100 where the aforementioned structures are formed, and the second conductive thin film is patterned through a patterning process to form a second insulation layer 212 and a second gate metal layer 203 arranged on the second insulation layer 212 in the second display region A2. In some examples, the second gate metal layer 203 may include: another plate of each of storage capacitors of a plurality of pixel circuits (e.g. a second electrode plate including a first capacitor C1).
(5) A first source-drain metal layer is formed. In some examples, a third insulation thin film is deposited on the base substrate 100 where the aforementioned patterns are formed, and the third insulation thin film is patterned through a patterning process to form a third insulation layer 213. The third insulation layer 213 of the second display region A2 may be provided with a plurality of via holes, which may expose, for example, surfaces of the semiconductor layer 201, the first gate metal layer 202, and the second gate metal layer 203, respectively. Subsequently, a third conductive thin film is deposited and patterned through a patterning process to form a first source-drain metal layer 204 on the third insulation layer 213 of the second display region A2. In some examples, the first source-drain metal layer 204 may include: first electrodes and second electrodes of transistors of a plurality of pixel circuits (e.g. including a first electrode and a second electrode of first transistor T1).
(6) A second source-drain metal layer is formed. In some examples, a fourth insulation thin film is deposited on the base substrate 100 where the aforementioned patterns are formed to form a fourth insulation layer 214; and subsequently, a fifth insulation thin film is coated and patterned through a patterning process to form a fifth insulation layer 215. In some examples, after a via or groove is formed in the fifth insulation layer 215, the fourth insulation layer 214 may be etched to form a via or groove provided in the fourth insulation layer 214 to expose a surface of the first source-drain metal layer 204. Subsequently, a fourth conductive thin film is deposited and patterned through a patterning process to form a second source-drain metal layer 205 on the fifth insulation layer 215 of the second display region A2. In some examples, the second source-drain metal layer 205 may include a plurality of first anode connection electrodes. The first anode connection electrodes may be configured to be electrically connected to first pixel circuits or second pixel circuits.
(7) A second transparent conductive layer is formed. In some examples, a sixth insulation thin film is coated on the base substrate 100 where the aforementioned patterns are formed, and the sixth insulation thin film is patterned through a patterning process to form a sixth insulation layer 216. Subsequently, a second transparent conductive thin film is deposited and patterned through a patterning process to form a second transparent conductive layer 302. In some examples, the second transparent conductive layer 302 may include a plurality of second anode connection electrodes, and a plurality of second connection lines 32, a plurality of fourth connection lines and a plurality of sixth connection lines which are located in the second display region A2. The second anode connection electrodes may be electrically connected to the first anode connection electrodes electrically connected to the second pixel circuits. The second connection line 32, the fourth connection line and the sixth connection line may be electrically connected to the first anode connection electrodes electrically connected to the first pixel circuits. The second connection line 32, the fourth connection line, and the sixth connection line may extend from the second display region A2 to the first display region.
(8) A first transparent conductive layer is formed. In some examples, a seventh insulation thin film is coated on the base substrate 100 where the aforementioned patterns are formed, and the seventh insulation thin film is patterned through a patterning process to form a seventh insulation layer 217. Subsequently, a first transparent conductive thin film is deposited and patterned through a patterning process to form a first transparent conductive layer 301 in the first display region A1. In some examples, the first transparent conductive layer 301 may include a plurality of first connection lines 31, a plurality of third connection lines, and a plurality of fifth connection lines.
(9) An anode layer, a pixel definition layer, an organic light emitting layer, a cathode layer and an encapsulation structure layer are formed in sequence. In some examples, an anode thin film is deposited on the base substrate 100 where the aforementioned patterns are formed, and the anode thin film is patterned through a patterning process to form an anode layer 401. For example, the anode layer 401 may include an anode 210 of a fourth light emitting element located in the second display region A2 and an anode 110 of a first light emitting element located in the first display region A1. There may be no insulation layer between the anode layer 210 and the first transparent conductive layer 301 of the first display region A1. The first connection line 31 of the first transparent conductive layer 301 may be in direct contact with the anode 110 of the first light emitting element. An anode 110 of one first light emitting element may be electrically connected to a second connection line 32 through a via hole formed on the seventh insulation layer 217 to achieve an electrical connection with a first pixel circuit of the second display region A2. The anode 210 of the fourth light emitting element may be electrically connected to the second anode connection electrode through a via hole formed on the seventh insulation layer 217 to achieve an electrical connection with a second pixel circuit. In this example, an orthographic projection of the first connection line 31 on the base substrate may not be overlapped with an orthographic projection of the via hole formed on the seventh insulation layer 217 on the base substrate, and the orthographic projection of the first connection line 31 on the base substrate may be overlapped with the anode 110 of the first light emitting element on the base substrate. However, the embodiment is not limited thereto. In some other examples, the first connection line may be electrically connected to the second connection line 32 through the via formed on the seventh insulation layer 217.

Subsequently, a pixel definition thin film is coated on the base substrate 100 where the aforementioned patterns are formed, and a pixel definition layer 402 is formed through mask, exposure, and development processes. The pixel definition layer 402 may be formed with a plurality of pixel openings exposing the anode layer. Subsequently, an organic light emitting layer is formed within the pixel openings. For example, the organic light emitting layer 211 of the fourth light emitting element of the second display region A2 is connected to the anode 210, and the organic light emitting layer 111 of the first light emitting element of the first display region A1 is connected to the anode 110. Subsequently, a cathode thin film is deposited, the cathode thin film is patterned through a patterning process to form a cathode layer 403, and the cathode layer 403 is electrically connected to the organic emitting layer and a second power supply line respectively. In some examples, an encapsulation structure layer 500 is formed on the cathode layer 403. The encapsulation structure layer 500 may include a stacked structure of inorganic material/organic material/inorganic material.

In some exemplary implementations, the first gate metal layer 202, the second gate metal layer 203, the first source-drain metal layer 204 and the second source-drain metal layer 205 may be made of metal materials, such as any one or more of silver (Ag), copper (Cu), aluminum (Al) and molybdenum (Mo), or alloy materials of the above metals, such as aluminum neodymium alloy (AlNd) or molybdenum niobium alloy (MoNb), and may be a single-layer structure or a multi-layer composite structure such as Mo/Cu/Mo. The first insulation layer 211, the second insulation layer 212, the third insulation layer 213, and the fourth insulation layer 214 may be made of any one or more of Silicon Oxide (SiOₓ), Silicon Nitride (SiNₓ), and Silicon Oxynitride (SiON), and may be a single layer, multiple layers, or a composite layer. The first insulation layer 211 and the second insulation layer 212 may be referred to as Gate Insulation (GI) layers, the third insulation layer 213 may be referred to as an Interlayer Dielectric (ILD) layer, and the fourth insulation layer 214 may be referred to as a passivation layer. The fifth insulation 215, the sixth insulation layer 216, and the seventh insulation layer 217 may be made of an organic material, such as polyimide, acrylic, or polyethylene terephthalate. The pixel definition layer 402 may be made of an organic material, such as polyimide, acrylic, or polyethylene terephthalate. The anode layer 401 may be made of a reflective material such as a metal, and the cathode layer 403 may be made of a transparent conductive material. However, the embodiment is not limited thereto.

In a manufacturing process of a display substrate of the embodiment, the first transparent conductive layer, the second transparent conductive layer and the seventh insulation layer are provided, which may achieve the electrical connection between the first pixel circuits and the first regional light emitting elements. Compared with the manufacturing scheme by using three transparent conductive layers and three insulation layers, the example may simplify the manufacturing process, is easy to implement, has high production efficiency, low production cost and high yield.

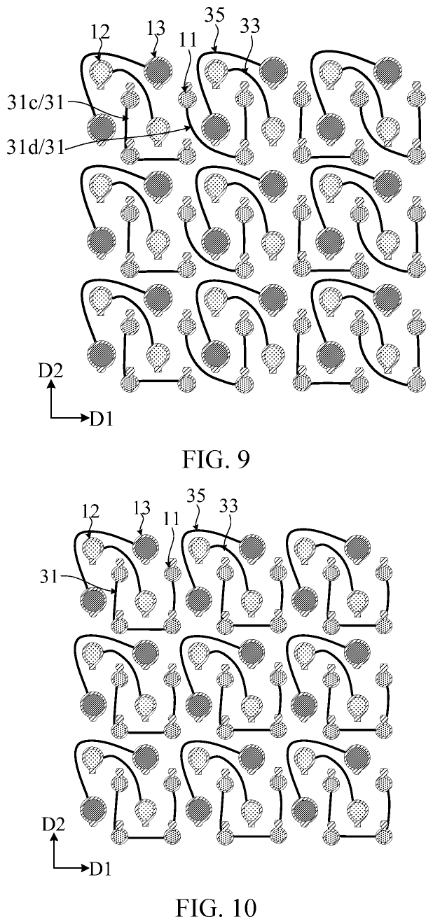

FIG. 8 is another schematic partial plan view of a display substrate according to at least one embodiment of the present disclosure. In some examples, as shown in FIG. 8, a plurality of first region light emitting elements in the first display region A1 may include a plurality of first light emitting elements 11 emitting first color light, a plurality of second light emitting elements 12 emitting second color light, and a plurality of third light emitting elements 13 emitting third color light. Two first light emitting elements 11 adjacent along the second direction Y may be electrically connected through a first connection line 31. For example, m and n may both be 2. An orthographic projection of the first connection line 31 on the base substrate may be I-shaped. Two first light emitting elements 11 electrically connected by the first connection line 31 may be electrically connected to one first pixel circuit of the second display region through a second connection line (not shown). The third connection line 33 may electrically connect the two second light emitting elements 12. The fifth connection line 35 may electrically connect the two third light emitting elements 13. At least a part of the first light emitting elements of the first display region A1 of the display substrate provided in this example may be electrically connected in such a manner that two first light emitting elements are driven by one first pixel circuit (i.e. one drives two). Rest of the structure of the display substrate according to this embodiment may be referred to descriptions of the aforementioned embodiments, and will not be repeated here.

FIG. 9 is another schematic partial plan view of a display substrate according to at least one embodiment of the present disclosure. In some examples, as shown in FIG. 9, a plurality of first region light emitting elements in the first display region A1 may include a plurality of first light emitting elements 11 emitting first color light, a plurality of second light emitting elements 12 emitting second color light, and a plurality of third light emitting elements 13 emitting third color light. Each first connection line 31 may electrically connect three first light emitting elements 11. For example, m and n may both be 3. The three first light emitting elements 11 to which each first connection line 31 is electrically connected may be arranged in two rows. The plurality of first connection lines 31 may include a plurality of third type first connection lines 31c and a plurality of fourth type first connection lines 31d. The three first light emitting elements 11 electrically connected by the third type first connection line 31c and the three first light emitting elements 11 electrically connected by the fourth type first connection line 31d may be arranged in a 2×3 array. Each third type first connection line 31c may be configured to electrically connect three adjacent first light emitting elements 11, wherein two of the first light emitting elements 11 are located in a same row, and two of the first light emitting elements 11 are located in a same column. The third type first connection line 31c may include two straight line segments, one of which electrically connects the two first light emitting elements 11 located in the same row, and the other of which electrically connects the two first light emitting elements 11 located in the same row. For example, an orthographic projection of the third type first connection line 31c on the base substrate may be L-shaped. Each fourth type first connection line 31d may be configured to electrically connect three adjacent first light emitting elements 11, wherein two of the first light emitting elements 11 are located in a same row, and two of the first light emitting elements 11 are located in a same column. The fourth type first connection line 31d may include one straight line segment and one arc line segment, wherein the straight line segment electrically connects the two first light emitting elements 11 located in the same column, and the arc line segment may electrically connect the two first light emitting elements 11 not located in the same row and the same column. For example, an orthographic projection of the fourth type first connection line 31d on the base substrate may be approximately V-shaped.

For example, first region light emitting elements partially surrounded by a third type first connection line 31c and a fourth type first connection line 31d adjacent to each other emit light of different colors. For example, a third type first connection line 31c partially surrounds a second light emitting element 12, and an adjacent fourth type first connection line 31d partially surrounds a third light emitting element 13. In the present disclosure, third type first connection line and fourth type first connection line adjacent to each other refer to that one first light emitting element electrically connected by the third type first connection line and one first light emitting element electrically connected by the fourth type first connection line are located in a same column.

In some examples, three first light emitting elements 11 electrically connected by the first connection line 31 may be electrically connected to one first pixel circuit of the second display region through a second connection line (not shown). The third connection line 33 may electrically connect the two second light emitting elements 12. The fifth connection line 35 may electrically connect the two third light emitting elements 13. An orthographic projection of the fifth connection line 35 on the base substrate may be V-shaped, and one second light emitting element 12 may be located in the V-shape formed by the fifth connection line 35. At least apart of the first light emitting elements of the first display region A1 of the display substrate provided in this example may be electrically connected in such a manner that three first light emitting elements are driven by one first pixel circuit (i.e. one drives three). Rest of the structure of the display substrate according to this embodiment may be referred to descriptions of the aforementioned embodiments, and will not be repeated here.

FIG. 10 is another schematic partial plan view of a display substrate according to at least one embodiment of the present disclosure. In some examples, as shown in FIG. 10, a plurality of first region light emitting elements in the first display region A1 may include a plurality of first light emitting elements 11 emitting first color light, a plurality of second light emitting elements 12 emitting second color light, and a plurality of third light emitting elements 13 emitting third color light. The first connection line 31 may electrically connect the four first light emitting elements 11. The four first light emitting elements 11 may be arranged in a 2×2 array. An orthographic projection of the first connection line 31 on the base substrate may be U-shaped. For example, one second light emitting element 12 may be located in the U-shape formed by the first connection line 31. One third light emitting element 13 is provided between adjacent first connection lines 31. Four first light emitting elements 11 electrically connected by the first connection line 31 may be electrically connected to one first pixel circuit of the second display region through a second connection line (not shown). The third connection line 33 may electrically connect the two second light emitting elements 12. The fifth connection line 35 may electrically connect the two third light emitting elements 13. At least part of the first light emitting elements of the first display region A1 of the display substrate provided in this example may be electrically connected in such a manner that fourth first light emitting elements are driven by one first pixel circuit (i.e. one drives fourth). Rest of the structure of the display substrate according to this embodiment may be referred to descriptions of the aforementioned embodiments, and will not be repeated here.

In some other examples, a part of the first light emitting elements of the first display region may be connected in a one-drive-two mode, and the another part of the first light emitting elements may be connected in a one-drive-three mode. For example, two rows of first light emitting elements may be connected in the order of electrically connecting three adjacent first light emitting elements, electrically connecting three adjacent first light emitting elements, and electrically connecting two adjacent first light emitting elements along the first direction. Alternatively, a part of the first light emitting elements of the first display region may be connected in a one-drive-three mode, and another part of the first light emitting elements may be connected in a one-drive-four mode. Alternatively, a part of the first light emitting elements of the first display region may be connected in a one-drive-two mode, another part of the first light emitting elements may be connected in a one-drive-three mode, and another part of the first light emitting elements may be connected in a one-drive-four mode. However, the embodiment is not limited thereto. This example can ensure the display quality and reduce the quantity of connection lines by adopting various drive connection modes, thus reducing the product cost.

An embodiment of the present disclosure further provides a manufacturing method of a display substrate, including: preparing a plurality of first pixel circuits and a plurality of second pixel circuits in a second display region of a base substrate, preparing a plurality of first region light emitting elements in a first display region of the base substrate, and preparing a plurality of second region light emitting elements in the second display region. Herein, the second display region is located on at least one side of the first display region; the plurality of first region light emitting elements include a plurality of first light emitting elements emitting the first color light; at least one second pixel circuit is electrically connected to at least one second region light emitting element and is configured to drive the at least one second region light emitting element to emit light; at least one first pixel circuit is electrically connected to the n first light emitting elements and is configured to drive the n first light emitting elements to emit light; at least one first pixel circuit is electrically connected to the m first light emitting elements and is configured to drive the m first light emitting elements to emit light; wherein m and n are integers greater than or equal to 2.

In some exemplary implementations, after the plurality of first pixel circuits and the plurality of second pixel circuits are prepared in the second display region of the base substrate, a plurality of first region light emitting elements are prepared in the first display region of the base substrate, and before the plurality of second region light emitting elements are prepared in the second display region, the manufacturing method further includes forming a second transparent conductive layer which includes a plurality of second connection lines, and forming a first transparent conductive layer in the first display region, wherein the first transparent conductive layer includes a plurality of first connection lines; the n first light emitting elements are electrically connected through one first connection line, the m first light emitting elements are electrically connected through one first connection line, and the n first light emitting elements or the m first light emitting elements which are electrically connected through the one first connection line are electrically connected to the first pixel circuit of the second display region through the second connection line. The first connection line is in direct contact with the anodes of the electrically connected first light emitting elements.

For the method for manufacturing the display substrate in this embodiment, reference may be made to descriptions of the aforementioned embodiments, and thus will not be repeated here.

An embodiment of the present disclosure further provides a display device, which includes the aforementioned display substrate.

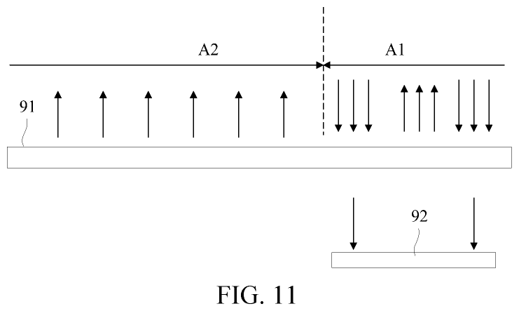

FIG. 11 is a schematic diagram of a display device according to at least one embodiment of the present disclosure. As shown in FIG. 11, an embodiment provides a display device, which includes a display substrate 91 and a photosensitive sensor 92 located on a light exit side of a display structure layer away from the display substrate 91. An orthographic projection of the photosensitive sensor 92 on the display substrate 91 is overlapped with the first display region A1.

In some examples, the display substrate 91 may be a flexible OLED display substrate, a QLED display substrate, a Micro-LED display substrate, or a Mini-LED display substrate. The display device may be any product or component with a display function such as an OLED display, a cell phone, a tablet, a television, a display, a laptop, a digital photo frame, and a navigator, which is not limited in the embodiments of the present disclosure.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display substrate, comprising:
a base substrate comprising a first display region and a second display region located on least one side of the first display region;
a plurality of first region light emitting elements located in the first display region, wherein the plurality of first region light emitting elements comprise a plurality of first light emitting elements emitting first color light;
a plurality of second region light emitting elements, a plurality of first pixel circuits and a plurality of second pixel circuits which are located in the second display region; wherein at least one second pixel circuit is electrically connected to at least one second region light emitting element and is configured to drive the at least one second region light emitting element to emit light; and
at least one first pixel circuit is electrically connected to n first light emitting elements and is configured to drive the n first light emitting elements to emit light; at least one first pixel circuit is electrically connected to m first light emitting elements and is configured to drive the m first light emitting elements to emit light; wherein m and n are integers greater than or equal to 2.

2. The display substrate according to claim 1, wherein the m first light emitting elements are first light emitting units and the n first light emitting elements are second light emitting units, and the first light emitting units and the second light emitting units are arranged at intervals along a first direction.

3. The display substrate according to claim 1, wherein m is an integer multiple of n.

4. The display substrate according to claim 1, wherein m is not equal to n.

5. The display substrate according to claim 1, further comprising: a plurality of first connection lines located in the first display region; the n first light emitting elements are electrically connected through one first connection line, and the m first light emitting elements are electrically connected through one first connection line; and each first connection line is in direct contact with anodes of the first light emitting elements to which the first connection line is electrically connected.

6. The display substrate according to claim 5, further comprising a plurality of second connection lines, wherein the n first light emitting elements or the m first light emitting elements which are electrically connected through the first connection line are electrically connected to a first pixel circuit of the second display region through a second connection line.

7. The display substrate according to claim 6, wherein the second connection lines are located on a side of the first connection lines close to the base substrate; a second connection line is electrically connected to the first connection line or an anode of at least one of the n first light emitting elements or the m first light emitting elements electrically connected to the first connection line.

8. The display substrate according to claim 7, wherein the first connection lines are located on a side of anodes of the first light emitting elements close to the base substrate; and an organic insulation layer is provided between the second connection lines and the first connection lines, and the second connection lines are electrically connected to the first connection lines or the anodes of the first light emitting elements through via holes formed on the organic insulation layer.

9. The display substrate according to claim 6, wherein materials of the first connection lines and the second connection lines comprise transparent conductive materials.

10. The display substrate according to claim 1, wherein m is 2 and n is 4; and the m first light emitting elements are arranged sequentially along a second direction, the n first light emitting elements are arranged in a 2×2 array, and the second direction intersects with the first direction.

11. The display substrate according to claim 6, wherein the plurality of first region light emitting elements further comprise: a plurality of second light emitting elements emitting second color light, and a plurality of third light emitting elements emitting third color light;
at least one first pixel circuit is electrically connected to two second light emitting elements through a third connection line and a fourth connection line, and at least one first pixel circuit is electrically connected to two third light emitting elements through a fifth connection line and a sixth connection line; and the third connection line and the fifth connection line are located in the first display region, and the fourth connection line and the sixth connection line extend from the second display region to the first display region and are electrically connected to the at least one first pixel circuit.

12. The display substrate according to claim 11, wherein the third connection line and the fifth connection line are arranged in a same layer as the first connection line, and the fourth connection line and the sixth connection line are arranged in a same layer as the second connection line.

13. The display substrate according to claim 11, wherein the first color light is green light, the second color light is red light, and the third color light is blue light.

14. The display substrate according to claim 11, wherein an orthogonal projection of the fifth connection line on the base substrate is V-shaped; and n or m is 4, and an orthographic projection of the first connection line electrically connected to four first light emitting elements on the base substrate is U-shaped.

15. The display substrate according to claim 11, wherein a plurality of rows of first region light emitting elements which are interconnected constitute a set of first region light emitting elements, one row of first region light emitting elements comprise a plurality of first region light emitting elements arranged along the first direction, and the fourth connection line to which second light emitting elements in the set of first region light emitting elements are electrically connected and the sixth connection line to which the third light emitting elements in the set of first region light emitting elements are electrically connected are located on a same side of the set of first region light emitting elements in the second direction; the second connection line to which first light emitting elements in the set of first region light emitting elements are electrically connected and the fourth connection line to which the second light emitting elements are electrically connected are located on opposite sides of the set of first region light emitting elements in the second direction; and the second direction intersects with the first direction.

16. The display substrate according to claim 1, wherein m and n are 3; the m first light emitting elements and the n first light emitting elements are arranged in a 2×3 array;
two first light emitting elements located in a same column and two first light emitting elements located in a same row in the m first light emitting elements are electrically connected through a first connection line; and two first light emitting elements located in a same column and two first light emitting elements which are not located in a same row or a same column in the n first light emitting elements are electrically connected through a first connection line.

17. A display device, comprising the display substrate according to claim 1.

18. A method for manufacturing a display substrate, comprising:
preparing a plurality of first pixel circuits and a plurality of second pixel circuits in a second display region of a base substrate;
preparing a plurality of first region light emitting elements in a first display region of the base substrate, and preparing a plurality of second region light emitting elements in the second display region; wherein the second display region is located on at least one side of the first display region; the plurality of first region light emitting elements comprise a plurality of first light emitting elements emitting first color light; at least one second pixel circuit is electrically connected to at least one second region light emitting element and is configured to drive the at least one second region light emitting element to emit light; at least one first pixel circuit is electrically connected to n first light emitting elements and is configured to drive the n first light emitting elements to emit light; at least one first pixel circuit is electrically connected to m first light emitting elements and is configured to drive the m first light emitting elements to emit light; wherein m and n are integers greater than or equal to 2.

19. The manufacturing method according to claim 18, after the plurality of first pixel circuits and the plurality of second pixel circuits are prepared in the second display region of the base substrate, a plurality of first region light emitting elements are prepared in the first display region of the base substrate, and before the plurality of second region light emitting elements are prepared in the second display region, the manufacturing method further comprises:
forming a second transparent conductive layer, which comprises a plurality of second connection lines;
forming a first transparent conductive layer in the first display region, wherein the first transparent conductive layer comprises a plurality of first connection lines; the n first light emitting elements are electrically connected through one first connection line, the m first light emitting elements are electrically connected through one first connection line, and the n first light emitting elements or the m first light emitting elements electrically connected through the first connection line are electrically connected to a first pixel circuit of the second display region through a second connection line; and the first connection line is in direct contact with anodes of the first light emitting elements to which the first connection line is electrically connected.

20. The display substrate according to claim 2, wherein m is an integer multiple of n.
